(19) United States
(12) Patent Application Publication
(10) Pub. No.: US 2008/0017904 A1
(43) Pub. Date: Jan. 24, 2008

(54) SEMICONDUCTOR DEVICE

(75) Inventors: Satoru AKIYAMA, Sagamihara (JP); Ryuta Tsuchiya, Hachioji (JP); Tomonori Sekiguchi, Tama (JP); Riichiro Takemura, Tokyo (JP); Masayuki Nakamura, Tokyo (JP); Yasushi Yamazaki, Tokyo (JP); Shigeru Shiratake, Tokyo (JP)

Correspondence Address: MILES & STOCKBRIDGE PC, 1751 PINNACLE DRIVE, SUITE 500, MCLEAN, VA, 22102-3833, US

(73) Assignees: Hitachi, Ltd.; Elpida Memory, Inc.

(21) Appl. No.: 11/773,990

(22) Filed: Jul. 6, 2007

(30) Foreign Application Priority Data
Jul. 20, 2006 (JP) JP2006-197602

(51) Int. Cl. H01L 27/108; H01L 21/8242

(52) U.S. Cl. 257/300; 438/241; 257/E21.646; 257/E27.084

(57) ABSTRACT

A DRAM capable of realizing reduced power consumption, high-speed operation, and high reliability is provided. A gate electrode configuring a memory cell transistor of the DRAM is composed of an n-type polysilicon film and a W (tungsten) film stacked thereon. A part of the polysilicon film is embedded in a trench formed in a silicon substrate in order to elongate the effective channel length of the memory cell transistor. The other part of the polysilicon film is located above the trench, and an upper surface thereof is located above a surface of the silicon substrate (p-type well). Therefore, distances between the W film and a source and drain (n-type semiconductor regions) are ensured.

### CROSS-REFERENCE TO RELATED APPLICATION

The present application claims priority from Japanese Patent Application No. JP 2006-197602 filed on Jul. 20, 2006, the content of which is hereby incorporated by reference into this application.

### TECHNICAL FIELD OF THE INVENTION

The present invention relates to a semiconductor device and a technique for manufacturing thereof. More particularly, the present invention relates to a technique effectively applied to a semiconductor device comprising Dynamic Random Access Memory (hereinafter, referred to as DRAM).

### BACKGROUND OF THE INVENTION

Dynamic Random Access Memory (hereinafter, referred to as DRAM), which is a kind of semiconductor memory devices, is mounted on a number of various electronic devices we use in daily life. Further, along with the needs for reduction in power consumption and enhanced performance of recent devices, enhancement in performance such as reduction in power consumption, speed-up, and increase in the capacity is strongly required for the mounted DRAM.

One of the most effective means for realizing high-performance DRAMs is to reduce the size of memory cell. When the memory cell size is reduced, the lengths of word lines and data lines connected to memory cells are shortened. Thus, the parasitic capacitance of the word lines and data lines is reduced, and low-voltage operation can be performed. Therefore, reduction in power consumption can be realized. In addition, since the memory cell size is reduced, the capacity thereof can be increased, and enhancement of the devices can be realized. As described above, reduction of the memory size largely contributes to enhancement of the performance of DRAMs.

However, as the reduction of the memory cell size advances to 65 nm node or 45 nm node, not only the above described effects of enhanced performance but also various adverse effects appear. A major adverse effect is increase in variation of device characteristics due to the reduction of the memory size. The variation of the element characteristics is, for example, dispersed values (deviation from mean values) of the magnitudes of the threshold voltages of memory cell transistors and leakage currents that flow from the memory cell transistors. Such variation of the device characteristics is desired to be suppressed to minimum as possible since it causes deterioration in the performance of DRAMs. Particularly, the threshold voltages of the memory cell transistors strongly affect data retention time of the DRAMs, thereby changing power consumption performance during a standby period. Therefore, the variation thereof is strongly desired to be reduced.

The threshold voltage variation of the memory cell transistors can be reduced by reducing manufacturing errors of channel length and channel widths. However, the manufacturing errors tend to be increased as scale-down progresses. Therefore, it is difficult to reduce the manufacturing errors more than the amount they have been conventionally reduced so as to reduce the threshold voltage variation. In other words, variation in the threshold voltages of cell transistors due to the short channel effect increases year by year.

When it is assumed that the variation of the threshold voltages is in conformity with normal distribution, and when variation (standard deviation σ) and the memory capacity (parameter) are increased, the threshold voltage of the memory cell in the worst condition is consequently reduced (or increased). Therefore, device designing such as setting a higher channel impurity concentration expecting threshold voltages which are reduced due to the short channel effect so as to compensate for the threshold voltage of the worst memory cell thereof is required. Alternatively, a means such as setting a high select level voltage (VPP) of word lines is also required so that sufficient signal levels can be programmed to storage nodes of memory cells even under unnecessarily increased threshold voltage conditions.

However, the former method has an adverse effect that the electric fields of the metallurgical junctions, i.e., so called PN junctions, in the substrate and diffusion layers of memory cells are increased, and junction leakage currents of memory cells are increased since a high channel impurity concentration is set and implanted into a silicon substrate. When the leakage currents are increased, data retention time is shortened, and the stand-by current of the DRAM is increased. On the other hand, when a high VPP level is set like the latter case, a higher select level voltage (VPP) has to be generated by an external power source (VDD), and the consumption current of the VPP power supply circuit is increased, in other words, there is an adverse effect that the operating current of the DRAM is increased. As described above, the designing means for suppressing reduction in the threshold voltage due to the short channel effect and reduction of consumption current during a stand-by period and the consumption current during operation are trade-off to each other.

Techniques disclosed in such as U.S. Pat. No. 6,939,765 (Patent Document 1) and Japanese Patent Application Laid-Open Publication No. 2001-210801 (Patent Document 2) are means for solving above described trade-off. Patent Document 1 discloses a technique for changing the structure of a memory cell transistor from a conventional planar type to a so-called trench type in order to suppress threshold voltage reduction due to the short channel effect. When the trench type memory cell structure is used, an effective channel length can be elongated although the gate length is same as that of the gate electrode of the planar type memory cell. As a result of the elongated channel length, threshold voltage variation caused by manufacturing errors can be reduced. In other words, the memory cell size can be reduced while suppressing the short channel effect. Therefore, the impurity concentration is not required to be increased more than necessary in order to compensate for reduction of the threshold voltage, and increase in the leakage current can be suppressed. Also, the VPP level is not required to be set unnecessarily high. Therefore, consumption current increase during operation is also suppressed.

### SUMMARY OF THE INVENTION

Meanwhile, according to a study by the inventors of the present invention about manufacturing techniques of DRAMs such as those described above, it have found out the facts described below.

When the memory cell structure is changed from the conventional planar type to the trench type, in the trench in which a channel region is formed, the parasitic capacitance of a word line is increased. In the case of the trench type memory cell structure, it is for the reason that, as shown in FIG. 24, a parasitic capacitance (COV) formed between part of a gate electrode 54 embedded in a trench 53 of a silicon substrate 52 and the silicon substrate 52 is newly added in addition to a word line parasitic capacitances (CW) which are generated between the electrode and a bit-line contact 50 and a storage-node contact 51. As a result, the time constant (RC) of the word line is increased, and delay is caused in access time (tRCD) from an active command to a read command.

According to the study by the inventors of the present invention, when the memory cell structure is changed from the planar type to the trench type, the access time is degraded by several ns. Therefore, change in design such as reducing the word line length more than a general memory array configuration is required. Kye Hyun Kyung et al. “A 800 Mb/s/pin 2 Gb DDR2 SDRAM using an 80 nm Triple Metal Technology”, IEEE International Solid-State Circuits Conference 2005, pp. 468-469 (Non-Patent Document) discloses an example in which the word line length is set to 256 Cell/WL so as to speed up the access time. However, although the access time (tRCD) can be speeded up when the word line length is shortened, there are problems that the number of sub word driver circuits (SWD) is increased since the number of division of a memory array is increased, and the chip size is thus increased.

Meanwhile, Patent Document 2 discloses a memory cell structure in which a gate electrode and a cap insulating film covering the gate electrode are embedded in a trench lower than the surface of a silicon substrate. By virtue of this structure, the parasitic capacitance formed between a word line and a storage-node contact and the parasitic capacitance formed between the word line and a bit-line contact can be reduced. Therefore, degradation of the access time (tRCD) can be suppressed.

However, a problem of this structure is that merely several nm of a gate oxide film is present between a stacked metal part such as W (tungsten), which is a part of a gate electrode material, and a diffusion layer region corresponding to a source and a drain. Therefore, in a manufacturing process of memory cells, sometimes, the gate electrode and the diffusion layer are brought into contact with each other, and a defect is caused. Also, abnormal oxidation is sometimes posed when the stacked metal part of the gate electrode is brought into contact with a silicon oxide film.

An object of the present invention is to provide a technique for reducing threshold voltage variation of a transistor constituting a memory cell of a DRAM and reducing power consumption during a stand-by period.

Another object of the present invention is to provide a technique for reducing a parasitic capacitance of word lines of the DRAM so as to suppress delay of access time.

Still another object of the present invention is to provide a technique for suppressing insufficient contact between a gate electrode and a diffusion layer, which may be caused upon memory cell formation of the DRAM, so as to improve reliability of the memory cells.

The above and other objects and novel characteristics of the present invention will be apparent from the description of this specification and the accompanying drawings.

The typical ones of the inventions disclosed in this application will be briefly described as follows.

An invention of the present application is a semiconductor device comprising a memory cell comprising a first field effect transistor formed on a main surface of a semiconductor substrate and a capacitative element connected to a source or a drain of the first field effect transistor, wherein as well as a part of a first gate electrode of the first field effect transistor is embedded in a trench formed in the semiconductor substrate, an upper surface of the first gate electrode projects above the surface of the semiconductor substrate.

Another invention of the present application is a method of manufacturing a semiconductor device comprising a memory cell comprising a first field effect transistor formed on a main surface of a semiconductor substrate and a capacitative element connected to a source or a drain of the first field effect transistor, wherein the method comprising a process of forming a first gate electrode of the first field effect transistor including the steps of: (a) forming a first insulating film on the main surface of the semiconductor substrate; (b) etching the first insulating film and the semiconductor substrate so as to form a trench; (c) forming a first gate insulating film of the first field effect transistor on the surface of the semiconductor device exposed in the trench; (d) forming a first conductive film for the first gate electrode on the first insulating film including the trench after the step (c); and (e) polishing the first conductive film by chemical mechanical planarization and causing the surface of the first insulating film to be exposed so that the first conductive film is formed having a part thereof is embedded in the trench whose upper surface is projected above the surface of the semiconductor substrate.

The effects obtained by typical aspects of the present invention will be briefly described below.

A part of a gate electrode of a memory cell transistor is embedded in a silicon substrate, and the effective channel length is elongated. As a result, the short channel effect is suppressed, and the threshold voltage variation can be reduced. Therefore, leakage currents can be reduced, refresh cycles can be extended, and power consumption during a stand-by period can be reduced.

A height of the gate electrode of the memory cell transistor from the surface of the silicon substrate is lowered so as to reduce the parasitic capacitance of a word line. Therefore, high-speed operation can be realized since the time constant of the word line can be reduced.

A metal film which is a part of the gate electrode of the memory transistor is formed higher than the silicon substrate surface. Consequently, short-circuit which may occur upon memory cell formation between the gate electrode and a source and drain can be reduced.

### BRIEF DESCRIPTIONS OF THE DRAWINGS

FIG. 1 is a cross-sectional view of main parts showing a configuration of a DRAM which is an embodiment of the present invention;

FIG. 2A is a circuit diagram showing word line parasitic capacitances of the DRAM which is an embodiment of the present invention;

FIG. 2B is a table showing the word line parasitic capacitances of the present embodiment and a conventional trench type memory cell, respectively, wherein the word line parasitic capacitance per 1 bit of a conventional planar type memory cell is defined as 1;

FIG. 3 is a cross-sectional view of main parts showing a method of manufacturing the DRAM which is an embodiment of the present invention;

FIG. 4 is a cross-sectional view of main parts showing the method of manufacturing the DRAM continued from FIG. 3;

FIG. 5 is a cross-sectional view of main parts showing the method of manufacturing the DRAM continued from FIG. 4;

FIG. 6 is a cross-sectional view of main parts showing the method of manufacturing the DRAM continued from FIG. 5;

FIG. 7 is a cross-sectional view of main parts showing the method of manufacturing the DRAM continued from FIG. 6;

FIG. 8 is a cross-sectional view of main parts showing the method of manufacturing the DRAM continued from FIG. 7;

FIG. 9 is a cross-sectional view of main parts showing the method of manufacturing the DRAM continued from FIG. 8;

FIG. 10 is a cross-sectional view of main parts showing the method of manufacturing the DRAM continued from FIG. 9;

FIG. 11 is a cross-sectional view of main parts showing the method of manufacturing the DRAM continued from FIG. 10;

FIG. 12 is a cross-sectional view of main parts showing the method of manufacturing the DRAM continued from FIG. 11;

FIG. 13 is a cross-sectional view of main parts showing the method of manufacturing the DRAM continued from FIG. 12;

FIG. 14 is a cross-sectional view of main parts showing the method of manufacturing the DRAM continued from FIG. 13;

FIG. 15 is a cross-sectional view of main parts showing the method of manufacturing the DRAM continued from FIG. 14;

FIG. 16 is a cross-sectional view of main parts showing the method of manufacturing the DRAM continued from FIG. 15;

FIG. 17 is a cross-sectional view of main parts showing the method of manufacturing the DRAM continued from FIG. 16;

FIG. 18 is a block diagram of a chip using the DRAM which is the embodiment of the present invention;

FIG. 19 is a circuit diagram showing a configuration example of a bank shown in FIG. 18;

FIG. 20 is a plan view showing a planar layout of a sub array shown in FIG. 19 and a sense amplifier array connected to the sub array;

FIG. 21 is a plan view showing an example of a memory cell layout of the DRAM which is the embodiment of the present invention;

FIG. 22 is a plan view showing another example of the memory cell layout of the DRAM which is the embodiment of the present invention;

FIG. 23 is a plan view showing another example of the memory cell layout of the DRAM which is the embodiment of the present invention; and

FIG. 24 is an explanatory diagram showing word line parasitic capacitances of a conventional trench-type memory cell.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

Although not limited to this, as a transistor configuring each block described in the embodiments, the transistor is formed on a single crystal silicon substrate by using an integrated circuit technique such as a known CMOS transistor (complementary MOS transistor) manufacturing technique. More specifically, the transistor is formed by a process including a step of forming a gate electrode and semiconductor regions constituting source and drain regions after forming a well, an isolation region, and a gate insulating film.

A circuit symbol of a MOSFET (Metal Oxide Semiconductor Field Effect Transistor) with a circle at a gate represents p-channel type MOSFET, and that without a circle represents n-channel type MOSFET. Hereinafter, MOSFET will be simply referred to as MOS transistor. Also, n-channel type MOS transistor and p-channel type MOS transistor will be simply referred to as nMOS transistor (NMOS) and pMOS transistor (pMOS), respectively. Furthermore, a MOS transistor configuring a memory cell is sometimes referred to as memory cell transistor, and a MOS transistor configuring a peripheral circuit is sometimes referred to as peripheral MOS transistor.

In the present invention, a MOS transistor includes not only a transistor having a gate insulating film formed of a silicon oxide film but also a general transistor such as a MISFET (Metal Insulator Semiconductor Field Effect Transistor) having a gate insulating film formed of an insulating material other than silicon oxide.

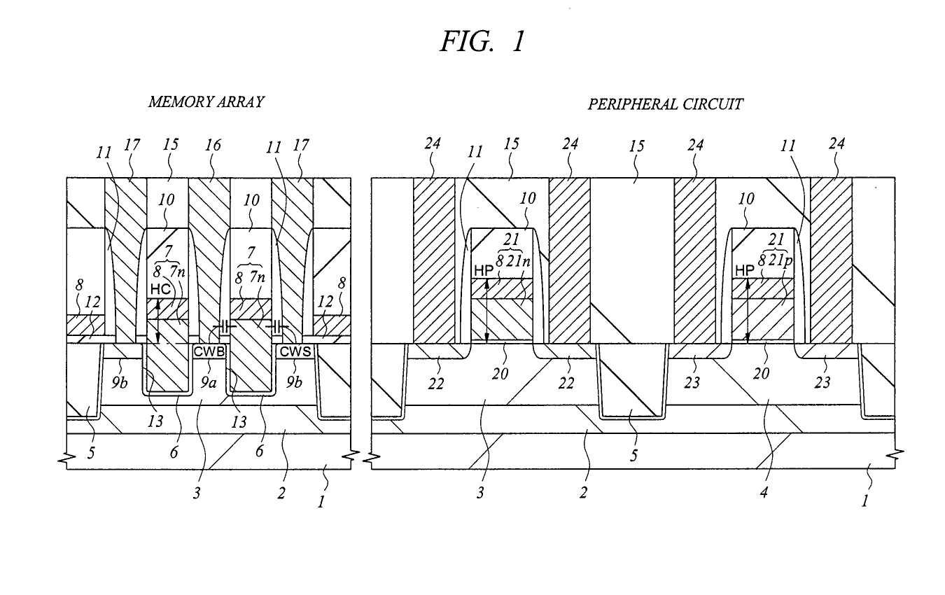

FIG. 1 is a cross-sectional view of main parts showing a configuration of a DRAM which is an embodiment of the present invention. The left part of FIG. 1 shows a memory cell formed in a memory array part, and the right part thereof shows MOS transistors (nMOS transistor and PMOS transistor) configuring a peripheral circuit part such as a sense amplifier, a main amplifier, a row decoder, and a column decoder.

In a p-type silicon substrate 1, an n-type buried well 2 to which an n-type impurity is implanted is formed. On the n-type buried well 2 of the memory array part, a p-type well 3 to which a p-type impurity is implanted is formed. On the n-type embedded well 2 of the peripheral circuit part, a p-type well 3 and an n-type well 4 are formed. In each of the p-type well 3 and the n-type well 4, an isolation trench 5 is formed.

The memory cell of the DRAM comprises an NMOS transistor and a capacitative element which is connected to the nMOS transistor in series. The nMOS transistor comprises a gate insulating film 6, a gate electrode 7 which is also serving as a word line, and n-type semiconductor regions 9a and 9b (source and drain). The gate electrode 7 is formed of a polysilicon film 7n doped with an n-type impurity and a W (tungsten) film stacked thereon. Over the W film 8, a cap insulating film 10 formed of a silicon oxide film is formed. A reference numeral 11 denotes a side wall spacer formed of a silicon nitride film, 12 denotes a sacrificial oxide film, and 13 denotes a trench.

Over the memory cell transistor, an interlayer insulating film 15 formed of a silicon oxide film or the like is formed. A bit-line contact 16 is formed in the interlayer insulating film 15 and over the n-type semiconductor region 9a, and a storage-node contact 17 is formed in the interlayer insulating film 15 over the n-type semiconductor region 9b. The bit-line contact 16 and the storage-node contact 17 are formed of contact holes formed in the interlayer insulating film 15 and an n-type polysilicon film embedded therein.

Although illustration is omitted, a bit line is formed over the bit-line contact 16, and a capacitative element is formed over the storage-node contact 17. The bit line is electrically connected to the n-type semiconductor region 9a via the bit-line contact 16, and the capacitative element is electrically connected to the n-type semiconductor region 9b via the storage-node contact 17.

The peripheral circuit part of the DRAM comprises the NMOS transistor formed on the p-type well 3 and the pMOS transistor formed on the n-type well 4. The nMOS transistor comprises a gate insulating film 20, a gate electrode 21, and n-type semiconductor regions 22 (source and drain). The gate electrode 21 is formed of an n-type polysilicon film 21n and the W film 8 stacked thereover, and the cap insulating film 10 is formed over the W film 8. The PMOS transistor is formed of the gate insulating film 20, a gate electrode 21, and p-type semiconductor regions 23 (source and drain). The gate electrode 21 is formed of a p-type polysilicon film 21p and the W film 8 stacked thereover, and the cap insulating film 10 is formed over the W film 8.

The interlayer insulating film 15 is formed over the peripheral MOS transistor. A wiring contact 24 is formed in the interlayer insulating film 15 over each of the n-type semiconductor region 22 and the p-type semiconductor region 23. The wiring contact 24 is formed of a contact hole formed in the interlayer insulating film 15 and a metal film such as a W film embedded therein. Although illustration is omitted, metal wirings are formed over the interlayer insulating film 15. The metal wires are electrically connected to the n-type semiconductor region 22 and the p-type semiconductor region 23 via the wiring contacts 24.

In the peripheral circuit part of the DRAM, in addition to the above described NMOS transistor and the PMOS transistor, a high-voltage nMOS transistor and a high-voltage (high-voltage) PMOS transistor configuring an input/output circuit or the like are formed (not shown). The high-voltage MOS transistors have a gate insulating film that is thicker than the gate insulating film 20 of the peripheral MOS transistor shown in FIG. 1. In the following description, unless otherwise stated, “a peripheral MOS transistor” (nMOS transistor, pMOS transistor) refers to the MOS transistor having the gate insulating film 20 such as that shown in FIG. 1.

As shown in FIG. 1, the gate electrode 7 of the memory cell transistor is formed of the n-type polysilicon film 7n and the W film 8, and part of the polysilicon film 7n is embedded in a trench 13 formed in the silicon substrate 1 (p-type well 3). The other part of the polysilicon film 7n projects above the trench 13, and the upper surface thereof is positioned higher than the surface of the silicon substrate 1 (p-type well 3).

When the gate electrode 7 of the memory cell transistor has above described structure, an effective channel length can be elongated without increasing the area of the memory cell. In other words, manufacturing errors can be reduced. Therefore, the threshold voltage reduction of the MOS transistor due to the short channel effect can be suppressed.

Moreover, since the short channel effect is suppressed, the concentration of the channel impurity implanted into the p-type well 3 is not required to be increased more than needed. In other words, when the threshold voltage is designed to be a level equivalent to that of a planar-type memory cell, a low concentration of the channel impurity can be set. As a result, the electric field of the metallurgical junction, i.e., so-called pn junction, between the p-type well 3 and the n-type semiconductor region 9b can be reduced. Therefore, the junction leakage current can be reduced. As a result, the data retention time is extended, and the stand-by current of the DRAM is reduced.

A reference character HC shown in the memory array part of FIG. 1 denotes the height from the surface of the silicon substrate 1 (p-type well 3) to the upper surface of the gate electrode 7. Also, a reference character HP shown in the peripheral circuit part denotes the height from the surface of the silicon substrate 1 (p-type well 3, n-type well 4) to the upper surface of the gate electrode 21. As shown in the drawing, in the DRAM of the present embodiment, the height (HC) from the surface of the silicon substrate 1 to the upper surface of the gate substrate 7 is smaller than the height (HP) from the surface of the silicon substrate 1 to the upper substrate of the gate electrode 21 (HC<HP). Therefore, compared to the case in which the height (HC) from the surface of the silicon substrate 1 to the upper surface of the gate electrode 7 is same as the height (HP) from the surface of the silicon substrate 1 to the upper surface of the gate electrode 21, the parasitic capacitance (CWB) generated between the bit-line contact 16 and the word line (gate electrode 7) and the parasitic capacitance (CWS) generated between the storage-node contact 17 and the word line (gate electrode 7) can be reduced.

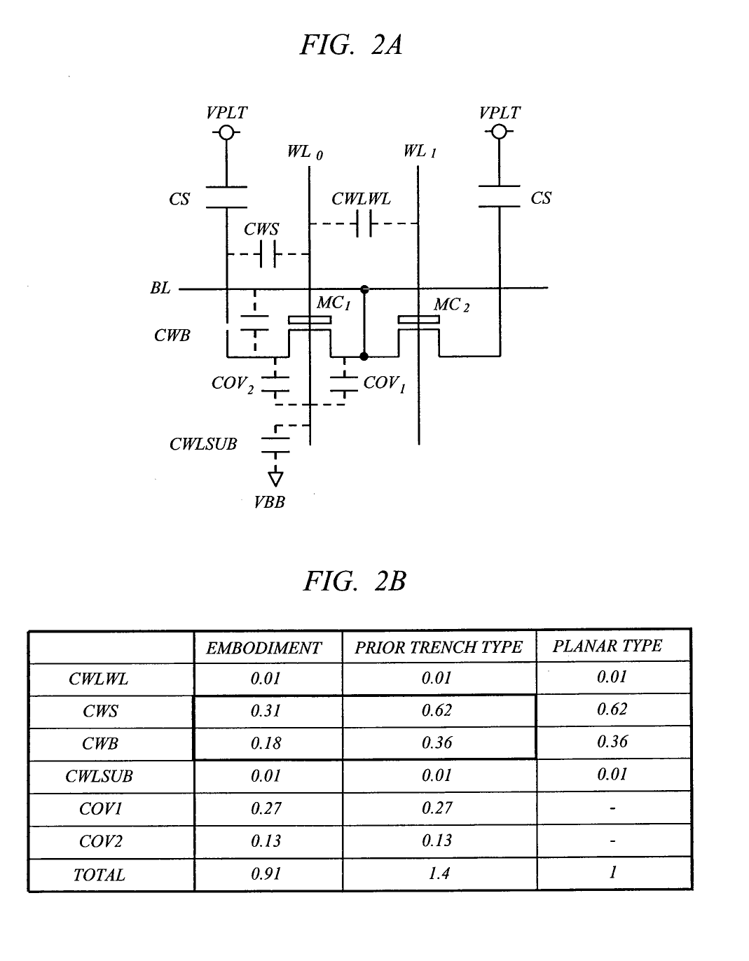

Study results of the word line parasitic capacitances in the DRAM of the present embodiment are shown in FIG. 2. FIG. 2A is a circuit diagram showing the parasitic capacitance of a word line WL₀ (gate electrode 7) connected to a memory cell MC₁. A reference character BL in the drawing represents a bit line, WL₁ represents a word line (gate electrode 7) connected to an adjacent memory cell MC₂, CS represents a capacitative element, VBB represents a substrate voltage, and VPLT represents a plate voltage. Also, CWLWL represents the parasitic capacitance between the word line WL₀ and the word line WL₁, CWS represents the parasitic capacitance between the word line WL₀ and the storage-node contact 17, CWB represents the parasitic capacitance between the word line WL₀ and the bit-line contact 16, CWLSUB represents the parasitic capacitance between the word line WL₀ and the silicon substrate 1, COV₁ represents the parasitic capacitance between the word line WL₀ (gate electrode 7) embedded in the trench 13 and the silicon substrate 1 in the n-type semiconductor region 9a side, and COV₂ represents the parasitic capacitance between the word line WL₀ (gate electrode 7) embedded in the grove 13 and the silicon substrate 1 in the n-type semiconductor region 9b side. FIG. 2B shows the word line parasitic capacitances (CWLWL, CWS, CWB, CWLSUB, COV₁, and COV₂) of the present embodiment and a conventional trench type memory cell, wherein the word line parasitic capacitance per 1 bit of a conventional planar type memory cell is defined as one.

In the present embodiment, the height (HC) from the surface of the silicon substrate 1 to the upper surface of the word line (gate electrode 7) is smaller than the height (HP) from the surface of the silicon substrate 1 and the upper surface of the gate electrode 21 of the peripheral circuit part. Consequently, the opposed area of the word line (gate electrode 7) and the bit-line contact 16 and the opposed area of the word line (gate electrode 7) and storage-node contact 17 are reduced to half compared to the conventional trench type memory cell. As a result, the parasitic capacitances (CWS and CWB) are also reduced to half as shown in FIG. 2B. Therefore, the entire parasitic capacitance of the word line is 0.91 times that of the conventional planar-type memory cell. As a result, increase of the time constant (RC) of the word line is suppressed. Therefore, delay in the access time (tRCD) from an active command to a read command can be suppressed.

On the other hand, in the conventional trench type memory cell, from the viewpoint of manufacturing cost reduction, a gate electrode of a memory transistor and a gate electrode of a peripheral MOS transistor are generally manufactured in the same step. However, in such a manufacturing method, the height of the gate electrode corresponding to the height (HC) of the gate electrode 7 of the memory cell of the present embodiment becomes same as the height (HP) of the gate electrode 21 formed in the peripheral circuit part. Therefore, the parasitic capacitance of the word line becomes larger than that of the present embodiment and becomes 1.4 times that of the conventional planar-type memory cell. More specifically, when a memory array is designed by applying the conventional trench type memory cell, delay is caused in the access time (tRCD). In order to prevent this, the word line length has to be shortened. Therefore, the dividing number of the memory array is increased, and the number of sub word circuits is increased. As a result, the chip size gets to be increased.

Moreover, in the present embodiment, the polysilicon film 7n configuring a part of the gate electrode 7 of the memory cell transistor is not completely embedded in the trench 13, but the upper surface thereof is positioned higher than the surface of the silicon substrate 1 (p-type well 3). Consequently, the polysilicon film 7n and the gate insulating film 6 are interposed between the W film 8 over the polysilicon film 7n and the source and drain (n-type semiconductor regions 9a and 9b). Therefore, failure where short-circuiting occurs between the W film 8 and the source and drain (n-type semiconductor regions 9a and 9b) during a manufacturing process of the memory cell can be suppressed. In order to reliably avoid the short-circuiting between the W film 8 and the source and drain (n-type semiconductor regions 9a and 9b), at least about 10 nm is desired to be ensured as the height from the surface of the silicon substrate 1 to the upper surface of the polysilicon film 7n.

Moreover, in the present embodiment, the thickness of polysilicon films (21n, 21p) configuring a part of the gate electrode 21 of the peripheral MOS transistor is, for example, about 30 nm to 80 nm. In other words, the height from the surface of the silicon substrate 1 to the upper surface of the polysilicon film (21n, 21p) is larger than the height from the surface of the silicon substrate 1 to the upper surface of the polysilicon film 7n. Thus, failure where the threshold voltage of the pMOS transistor is varied when part of B (boron) implanted into the p-type polysilicon film 21p penetrates into the silicon substrate 1 can be suppressed.

Moreover, in the present embodiment, the upper surface of the cap insulating film 10 covering the gate electrode 7 of the memory cell transistor and the upper surface of the cap insulating film 10 covering the gate electrode 21 of the peripheral MOS transistor have the same height. Consequently, the height from the surface of the silicon substrate 1 to the upper surface of the interlayer insulating film 15 becomes approximately the same in the memory array part and the peripheral circuit part. Thus, the surface unevenness of the interlayer insulating film 15 is reduced. Therefore, processing of the metal wires formed on the interlayer insulating film 15 is facilitated.

In the present embodiment, each of the gate electrodes 7 and 21 has a stacked structure of a polysilicon film and a W film in order to reduce the electric resistance values of the gate electrode 7 (word line) and the gate electrode 21. Meanwhile, a barrier layer formed of a WN film or the like may be formed in order to prevent reaction between the polysilicon film and the W film. Further, each of the gate electrodes 7 and 21 may comprise a single-layer conductive film such as a polysilicon film or a metal film instead of the stacked film.

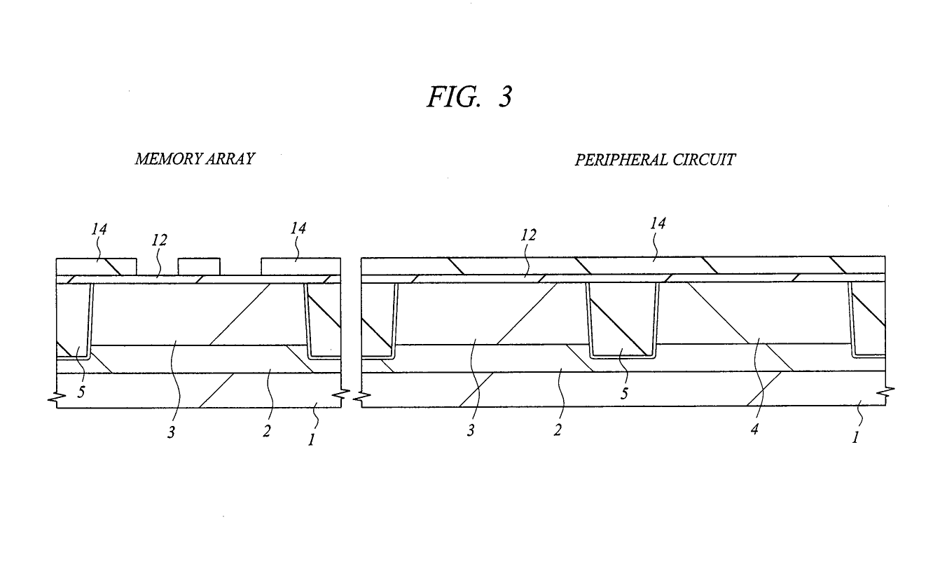

Next, a method of manufacturing the DRAM of the present embodiment will be described with reference to FIG. 3 to FIG. 17. First, as shown in FIG. 3, the n-type buried well 2, the p-type well 3, and the n-type well 4 are formed in the silicon substrate 1 by using known manufacturing techniques, and the isolation trenches 5 are formed in the p-type well 3 and the n-type well 4. Then, the sacrificial oxide film 12 is deposited on the silicon substrate 1 by CVD, a silicon nitride film 14 is subsequently deposited on the sacrificial oxide film 12 by CVD, and a part of the silicon nitride film 14 is removed by dry etching using a photo resist film as a mask.

Next, in order to adjust the threshold voltages of the memory cell transistors and the peripheral MOS transistors, a p-type impurity (boron) is ion implanted to the p-type well 3. At this point, the surface of the p-type well 3 is covered with the sacrificial oxide film 12. Therefore, damage of the p-type well 3 caused by the ion implantation of boron or variation in the channel impurity concentration due to channeling of boron can be suppressed.

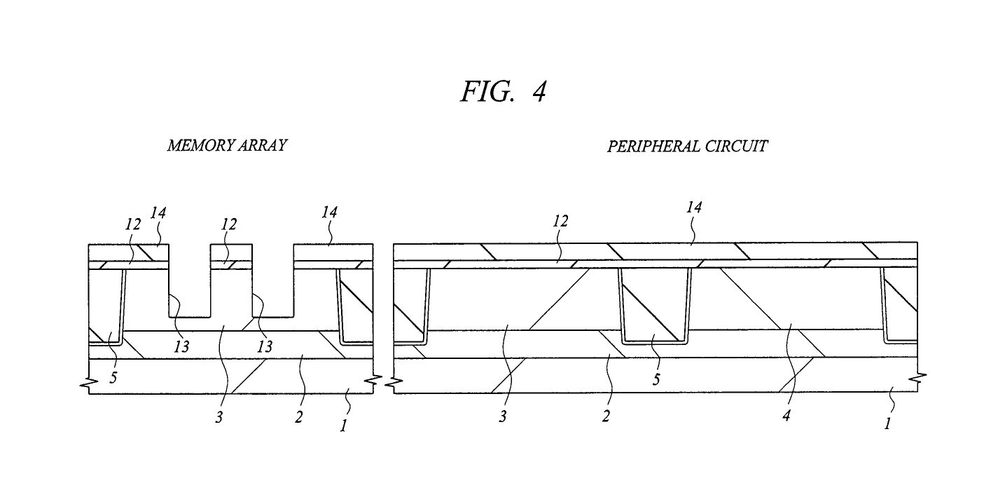

Next, as shown in FIG. 4, the sacrificial oxide film 12 and the p-type well 3 of the memory array part are dry etched by using the silicon nitride film 14 as a mask, thereby forming the trenches 13 which will serve as channel regions of the memory cell transistors. Note that, the impurity for threshold voltage adjustment may be ion implanted after the trenches 13 are formed. In this case, the impurity can be introduced into the entire channel formation regions in the trenches 13 by ion implanting the impurity to the surface of the p-type well 3 in the vertical direction and an oblique direction.

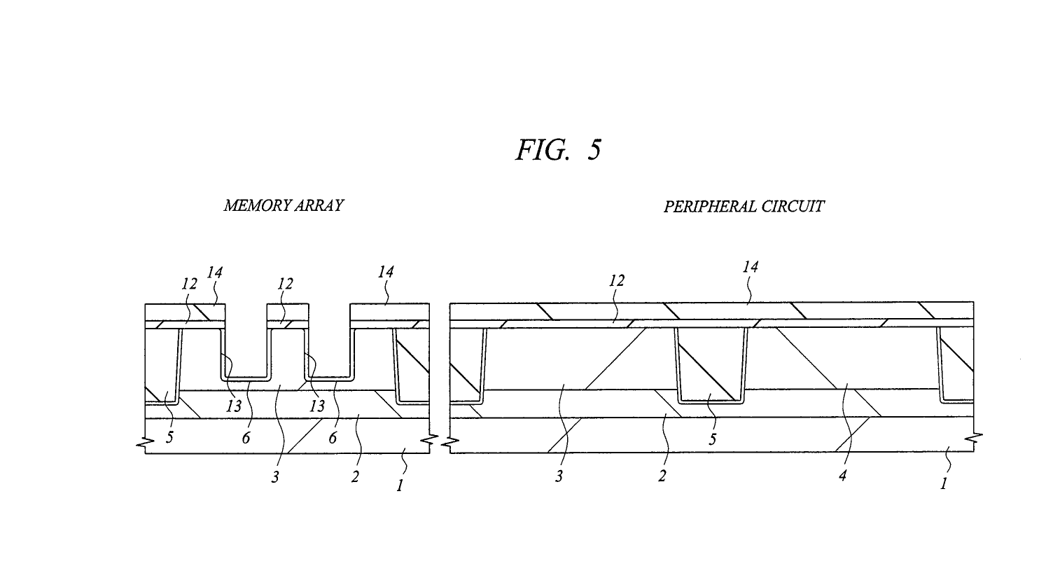

Next, as shown in FIG. 5, the gate insulating film 6 of the memory cell transistors is formed over the inner wall of the trenches 13 by thermally oxidizing the p-type well 3. Preferably, the thickness of the gate isolation film 6 is about 4 nm to 10 nm. When the thickness of the gate insulating film 6 is thinner than 4 nm, a gate leakage current is generated, and the data retention characteristic of the memory cell is readily deteriorated. When the thickness of the gate insulating film 6 is larger than 10 nm, writing a high-level signal to the memory cell may become insufficient since the threshold voltage of the memory cell transistor is increased.

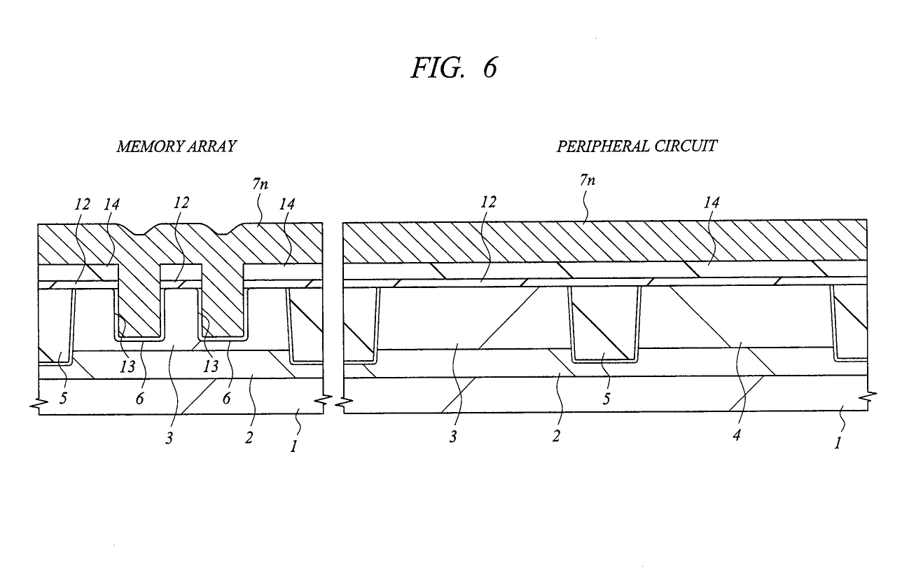

Next, as shown in FIG. 6, after the polysilicon film 7n doped with an n-type impurity is deposited on the silicon substrate 1 by CVD, activation annealing is performed. The polysilicon film 7n embedded in the trenches 13 will serve as a part of the gate electrodes 7 of the memory cell transistors. Note that an amorphous silicon film may be deposited instead of the polysilicon film 7n. Also, a p-type impurity (boron) may be doped instead of the n-type impurity. When a part of the gate electrode 7 is formed of a p-type polysilicon film, the memory cell transistor will be a so-called p⁺-gate transistor. Therefore, even when the impurity concentration implanted into the channel region is reduced, a desired threshold voltage can be ensured. Thus, the electric field of the pn junction is relaxed, and the leakage current is reduced. Therefore, the power consumption during a stand-by period of the DRAM can be suppressed at a low level.

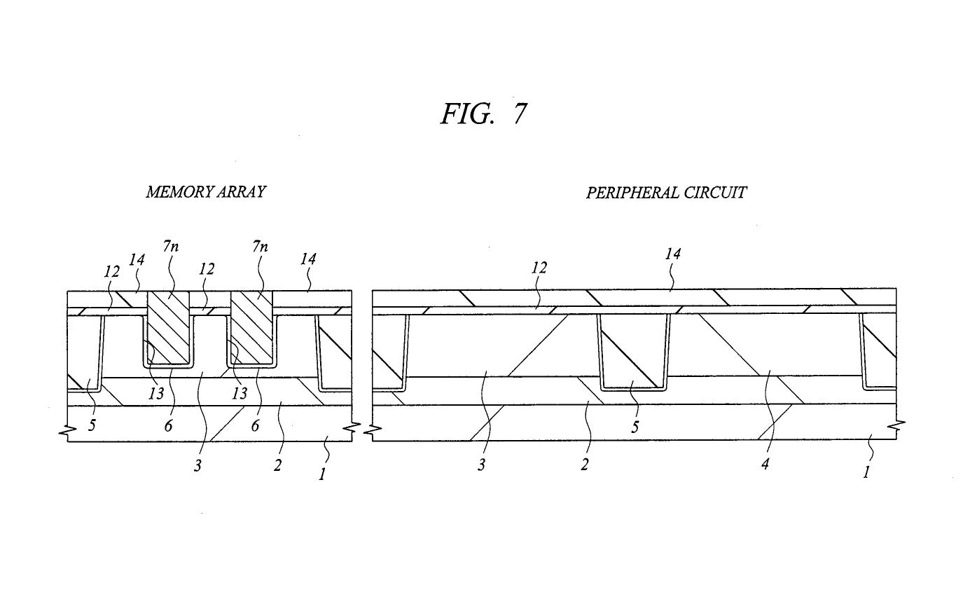

Next, as shown in FIG. 7, the polysilicon film 7n is polished by chemical mechanical planarization (CMP) method. In this case, polishing is stopped when the surface of the silicon nitride film 14 is exposed. As a result, the polysilicon film 7n of which surface is planarized is caused to remain in the trenches 13. In this manner, by subjecting the polysilicon film 7n to chemical mechanical planarization by using the silicon nitride film 14 as a stopper film, the height from the surface of the p-type well 3 to the upper surface of the polysilicon film 7n can be controlled with high precision.

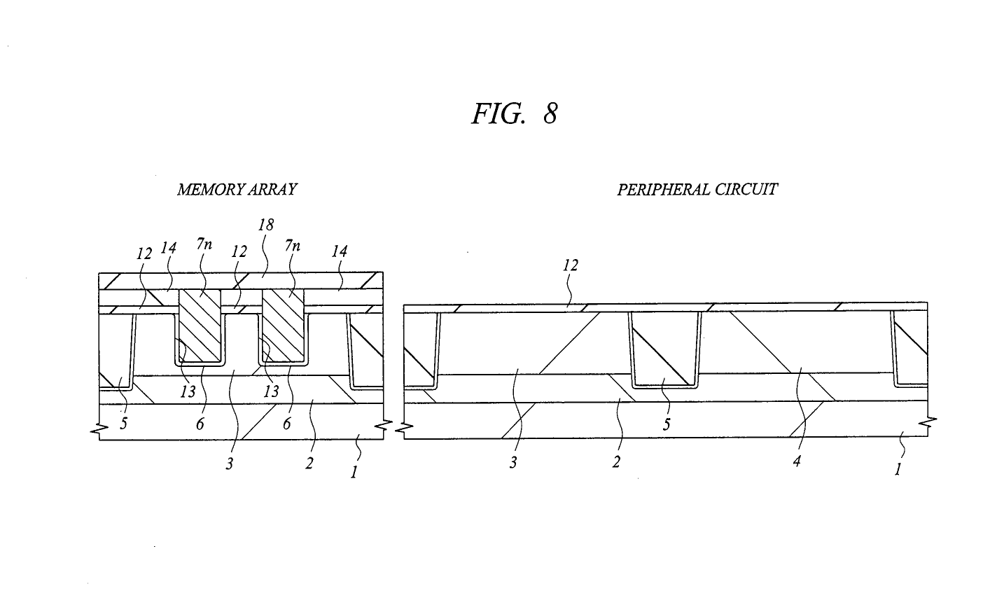

Next, as shown in FIG. 8, after a silicon nitride film 18 is deposited on the silicon substrate 1 by CVD, the silicon nitride film 18 and the silicon nitride film 14 are removed by dry etching using a photo resist film as a mask. The silicon nitride film 18 remaining in the memory array part will serve as a hard mask which protects the surface of the polysilicon film 7n in etching or annealing performed in the following steps.

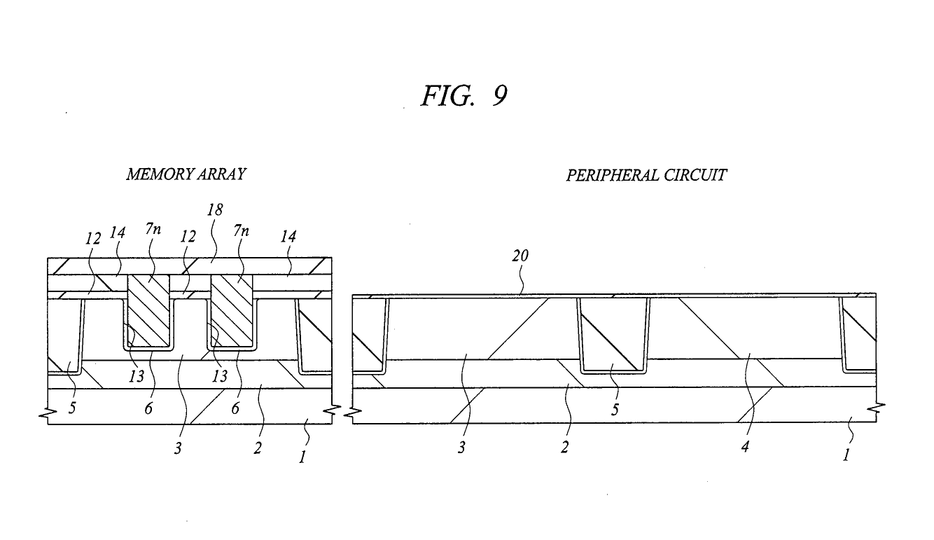

Next, as shown in FIG. 9, after the sacrificial oxide film 12 of the peripheral circuit part is removed by wet etching, the silicon substrate 1 is subjected to thermal oxidation, thereby forming the gate insulating film 20 on the surfaces of the p-type well 3 and the n-type well 4 of the peripheral circuit part, respectively. Note that, in part of the peripheral circuit part (input/output circuit or the like), a high-voltage MOS transistor having a gate insulating film that is thicker than the gate insulating film 20 is formed. In order to form the thick gate insulating film of the high-voltage MOS transistor, after the gate insulating film 20 is formed, the memory array part and the peripheral circuit part except for the high-voltage MOS transistor formation region is covered with a photo resist film, and a silicon oxide film is deposited on the gate insulating film 20 of the high-voltage MOS transistor formation region by CVD. The high-voltage MOS transistor can be manufactured in accordance with a known manufacturing method. Therefore, merely the method of manufacturing the MOS transistor having the thin gate insulating film 20 is described for the peripheral circuit part.

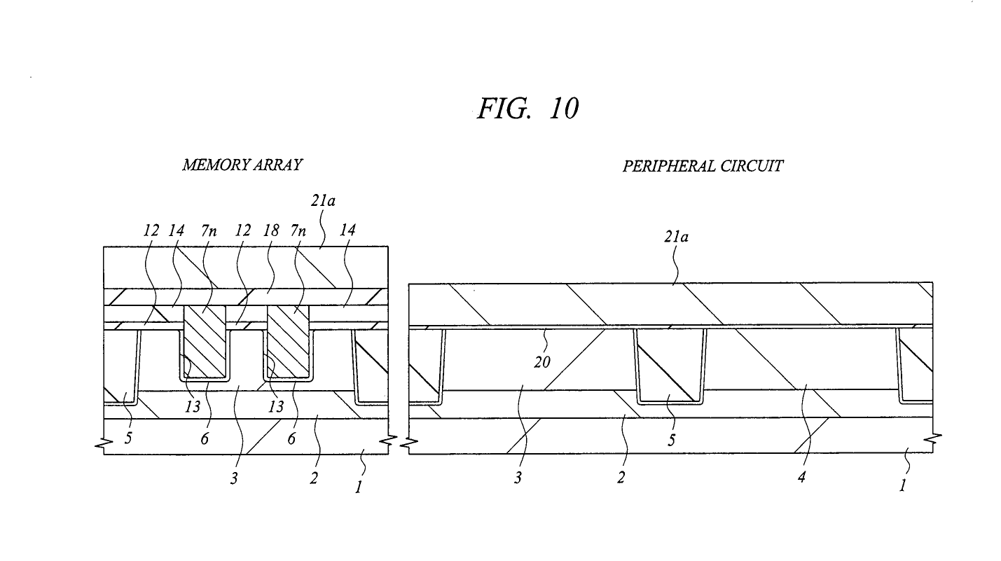

Next, as shown in FIG. 10, a polysilicon film 21a is deposited on the silicon substrate 1 by CVD. The polysilicon film 21a is a so-called non-doped polysilicon film to which impurities are not doped. Instead of the non-doped polysilicon film, a non-doped amorphous silicon film may be deposited. The thickness of the polysilicon film 21a is about 30 nm to 80 nm so that the upper surface of the polysilicon film 21a deposited on the peripheral circuit part is higher than the upper surface of the polysilicon film 7n formed in the memory array part.

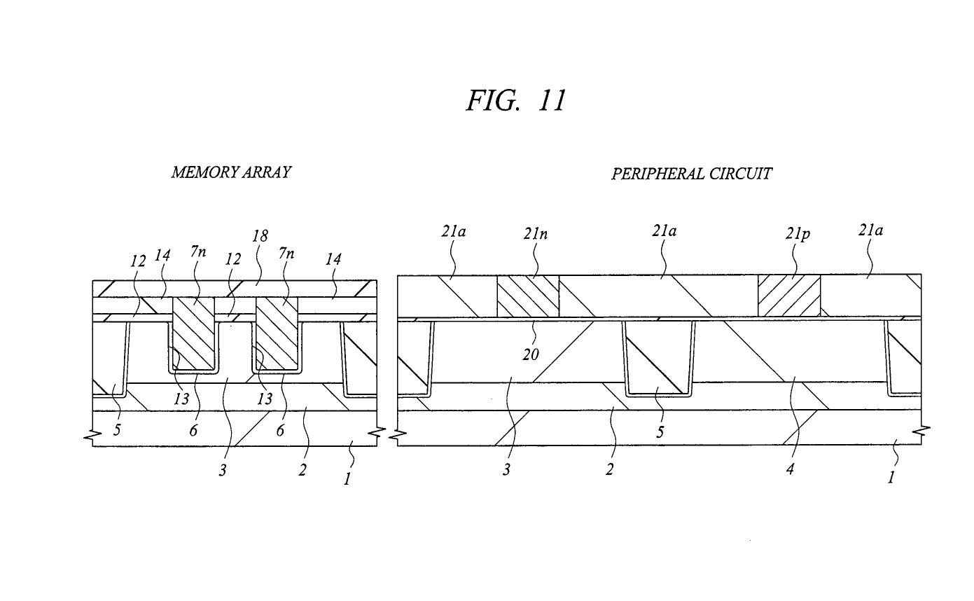

Next, as shown in FIG. 11, the polysilicon film 21a of the memory array part is removed by dry etching using a photo resist film as a mask. Subsequently, an n-type impurity (for example, phosphorus) is ion implanted into the part of the polysilicon film 21a (gate electrode formation region of the nMOS transistor) of the peripheral circuit part, thereby forming the n-type polysilicon film 21n. A p-type impurity (boron) is ion implanted into the other part of the polysilicon film 21a (gate electrode formation region of the p-MOS transistor) of the peripheral circuit part, thereby forming the p-type polysilicon film 21p.

As described above, in the present embodiment, the nMOS transistor of the peripheral circuit part is formed to be a so-called n⁺-gate transistor, and the PMOS transistor thereof is formed to be a p⁺-gate transistor. Meanwhile, when both the nMOS transistor and the pMOS transistor are formed to be n⁺-gate transistors, an n-type impurity (for example, phosphorus) is ion implanted also into the polysilicon film configuring the gate electrode of the pMOS transistor. Therefore, the threshold voltage of the pMOS transistor is increased although steps can be simplified. Conventionally, as a countermeasure therefor, although an impurity having a polarity opposite to that of a normal channel impurity is subjected to counter-dope into the channel region of the pMOS transistor so as to form a buried channel structure, in the MOS transistor having the buried channel structure, the short channel effect readily appears compared to a MOS transistor having the surface channel structure. In the present embodiment, so-called dual gate structure in which the nMOS transistor of the peripheral circuit part is an n⁺-gate type and the pMOS transistor is p⁺-gate type is employed. Therefore, the short channel effect is suppressed. As a result, characteristics of the peripheral MOS transistors are consequently improved.

Moreover, in the present embodiment, the polysilicon film 7n serving as a part of the gate electrodes 7 of the memory cell transistors and the polysilicon film 21a serving as a part of the gate electrodes 21 of the peripheral MOS transistors are deposited in separate steps. Therefore, the thickness of each of the polysilicon films can be optimized. In other words, the gate electrode 7 of the memory cell transistor may be arranged so that the thickness of the polysilicon film 7n on the surface of the silicon substrate 1 is about 10 nm in order to reduce the parasitic capacitance of the word line. Meanwhile, the gate electrode 21 of the pMOS transistor of the peripheral circuit part may be arranged so that the thickness of the polysilicon film 21p is increased up to 30 nm to 80 nm so as to suppress characteristic deterioration caused by boron penetration.

Moreover, in the present embodiment, after the gate electrode 7 of the memory cell transistor is formed, the gate electrode 21 of the peripheral MOS transistor is formed. Therefore, when planarizing the surface of the gate electrode 7, chemical mechanical planarization exhibiting good controllability can be used. Thus, an interval between the W film 8 deposited on the polysilicon film 7n and the source and drain (n-type semiconductor regions 9a and 9b) can be ensured. Thus, short-circuiting therebetween can be reliably avoided.

As another method of manufacturing the peripheral MOS transistors, a part of the gate electrode of the nMOS transistor can be formed by using the polysilicon film 7n serving as a part of the gate electrodes 7 of the memory transistors. In this case, when the PMOS transistor is formed to be p⁺-gate type, a polysilicon film which will serve as a part of the gate electrode of the PMOS transistor is desired to be deposited in a separate step. A reason therefor is that, when the pMOS transistor is formed to be p⁺-gate type by using the polysilicon film 7n with an n-type impurity doped thereto, the characteristics of the pMOS transistor may be deteriorated due to the damage caused by ion implantation since the polarity has to be reversed by doping a large amount of a p-type impurity into the polysilicon film 7n. Meanwhile, when the pMOS transistor is formed to be n⁺-gate type, the manufacturing processes can be simplified since a part of the gate electrode of the pMOS transistor can be formed by using the polysilicon film 7n. However, in that case, deterioration in characteristics due to the short channel effect is readily caused since the PMOS transistor has a buried-channel structure.

When a part of the gate electrodes 7 of the memory cell transistor is formed by a p-type polysilicon film, a part of the gate electrode of the pMOS transistor formed in the peripheral circuit part can be also formed by the p-type polysilicon film. In this case, when the NMOS transistor formed in the peripheral circuit part is n⁺-gate type, an n-type polysilicon film is desired to be deposited in a separate step.

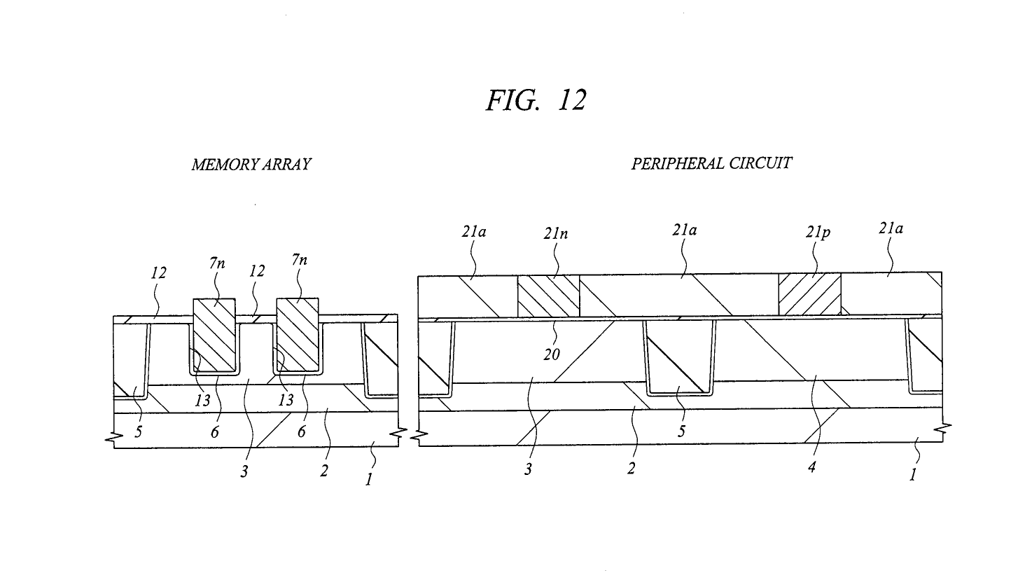

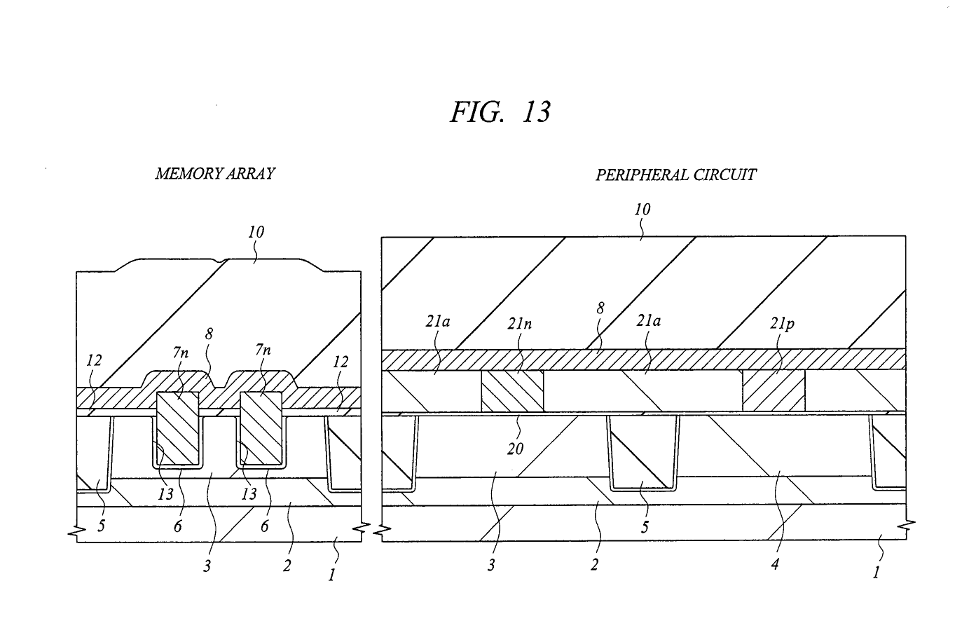

Next, as shown in FIG. 12, the silicon nitride film 18 and the silicon nitride film 14 of the memory array part are removed by dry etching using a photo resist film as a mask. Then, as shown in FIG. 13, the W film 8 is deposited on the silicon substrate 1 by CVD, and the cap insulating film 10 formed of a silicon oxide film is subsequently deposited on the W film 8 by CVD. As a conductive film serving as a part of the gate electrodes 7 and 21, a metal film such as a Ti (titanium) film or a Ni (nickel) film or a multi-layered metal film of, for example, a W film/WN film/WSi film may be used instead of the W film 8.

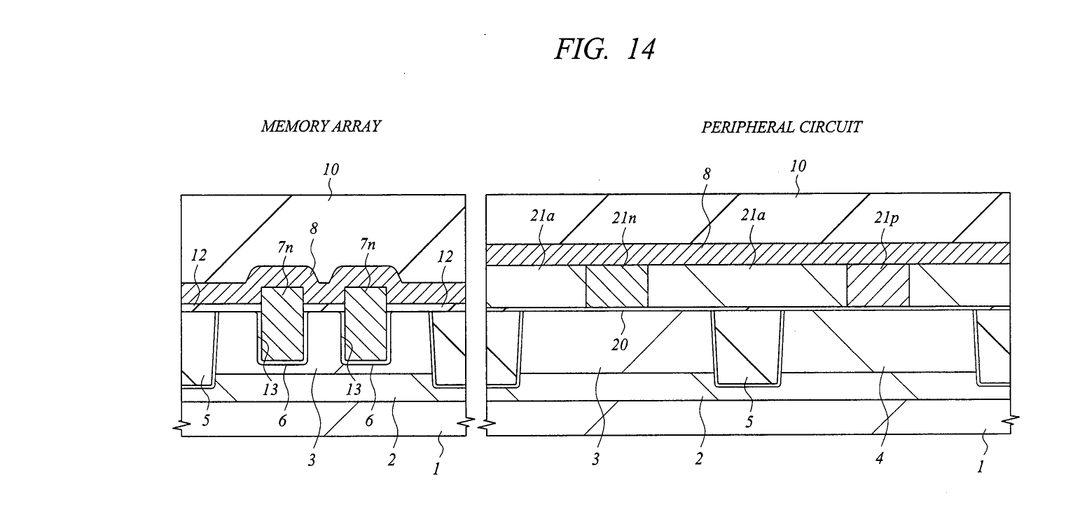

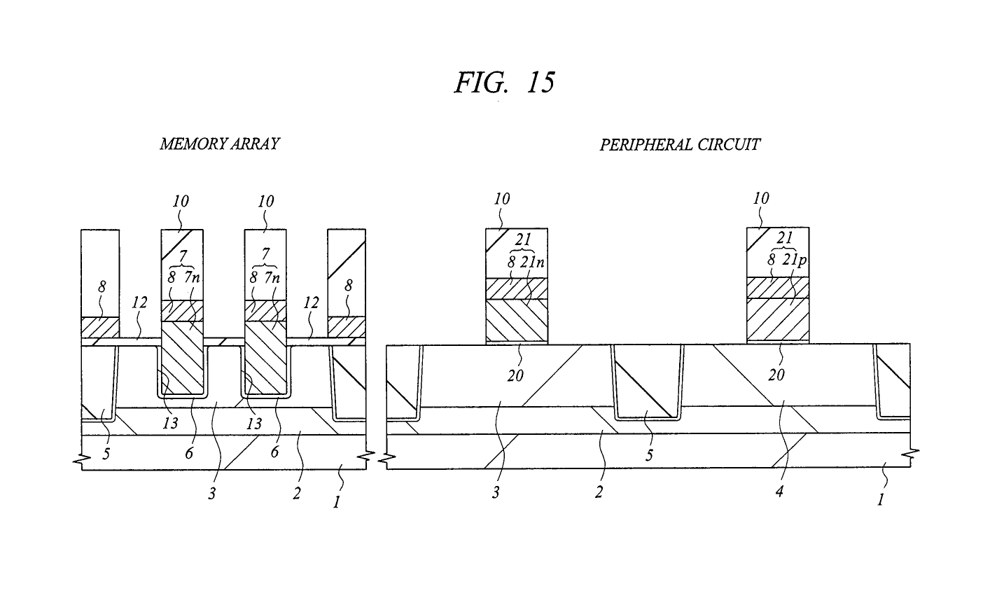

Next, as shown in FIG. 14, the cap insulating film 10 is planarized by chemical mechanical planarization, thereby equalizing the height of the upper surface of the cap insulating film 10 in the memory array part and the peripheral circuit part. Subsequently, as shown in FIG. 15, the cap insulating film 10, the W film 8, and the polysilicon film 7n of the memory array part is subjected to dry etching using a photo resist film as a mask, thereby forming the gate electrodes 7 of the memory cell transistors. Also, the cap insulating film 10, the W film 8, and the polysilicon film 21a of the peripheral circuit part are subjected to dry etching, thereby forming the gate electrode 21 of the nMOS transistor and the gate electrode 21 of the PMOS transistor.

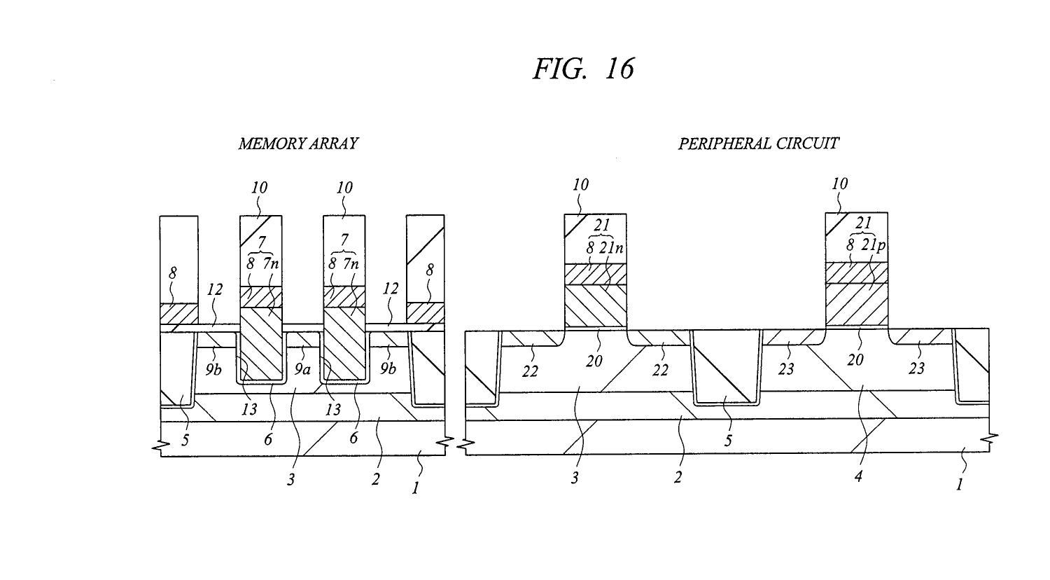

Next, as shown in FIG. 16, an n-type impurity is ion implanted into the p-type well 3 of the memory array part and the p-type well 3 of the peripheral circuit part, thereby forming the n-type semiconductor regions 9a and 9b (source and drain) of the memory cell transistor and the n-type semiconductor regions 22 (source and drain) of the nMOS transistor of the peripheral circuit part. Also, a p-type impurity is ion implanted into the n-type well 4 of the peripheral circuit part, thereby forming the p-type semiconductor regions 23 (source and drain) of the pMOS transistor. In order to individually optimize the impurity concentrations of the n-type semiconductor regions 9a and 9b and the n-type semiconductor regions 22, ion implantation of n-type impurities may be performed in separate steps for the p-type well 3 of the memory array part and the p-type well 3 of the peripheral circuit part.

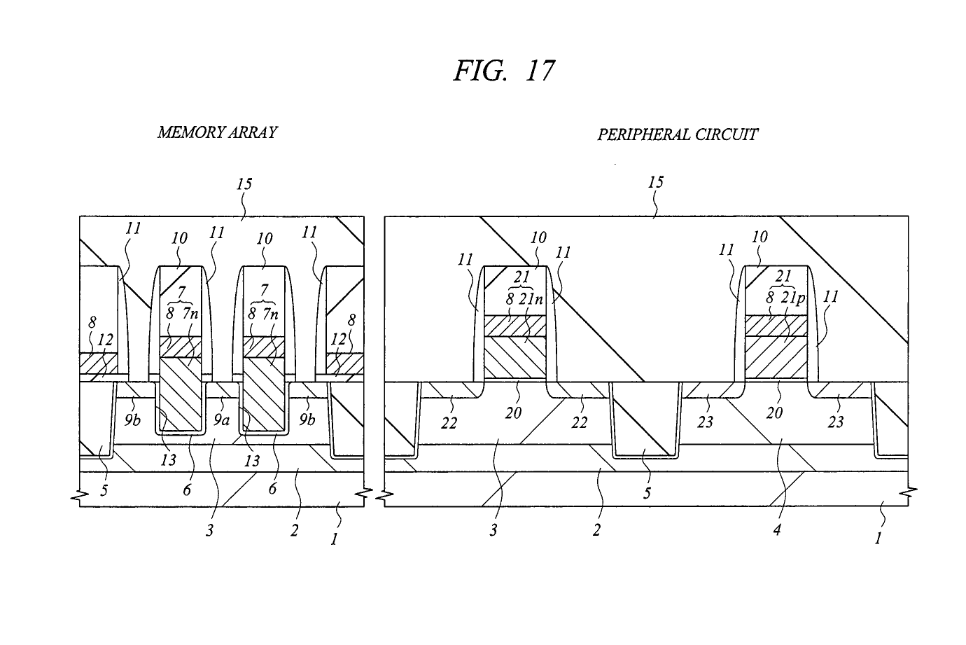

Next, as shown in FIG. 17, after a silicon nitride film is deposited on the silicon substrate 1 by CVD, the silicon nitride film is etched, thereby forming sidewall spacers 11 on the sidewalls of each of the gate electrodes 7 and 21. Subsequently, after the interlayer insulating film 15 formed of a silicon oxide film is deposited on the silicon substrate 1 by CVD and planarized by chemical mechanical planarization, thereby equalizing the height of the upper surface of the interlayer insulating film 15 in the memory array part and the peripheral circuit part.

Then, the bit-line contact 16 and the storage-node contacts 17 are formed in the interlayer insulating film 15 of the memory array part, and the wiring contacts 24 are formed in the interlayer insulating film 15 of the peripheral circuit part, thereby obtaining the DRAM of the present embodiment which is shown in FIG. 1 described above. Note that, in an actual method of manufacturing a DRAM, metal wires including bit lines and capacitative elements are formed over the interlayer insulating film 15. However, descriptions thereof will be omitted since the metal wires and capacitative elements can be manufactured according to known manufacturing methods.

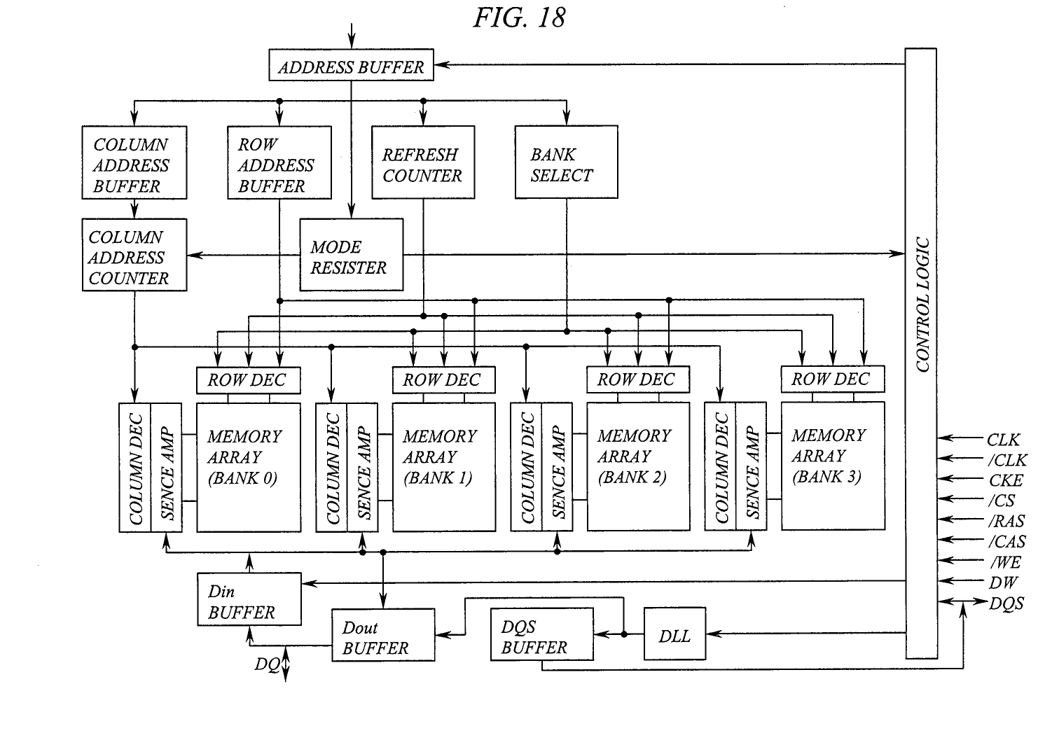

FIG. 18 shows a block diagram of the case in which a DRAM chip is designed by using memory cells which are manufactured according to the method of manufacturing described above. The reference characters shown in the diagram represent: an address buffer (ADDRESS BUFFER); a column address buffer (COLUMN ADDRESS BUFFER); a column address counter (COLUMN ADDRESS COUNTER); a row address buffer (ROW ADDRESS BUFFER); a refresh counter (REFRESH COUNTER); a bank select (BANK SELECT); a mode resistor (MODE RESISTOR); a row decoder (ROW DEC); a column decoder (COLUMN DEC); a main sense amplifier (SENSE AMP); a memory array (MEMORY ARRAY); a data input buffer (Din BUFFER); a data output buffer (Dout BUFFER); a data buffer (DQS BUFFER); a delay locked loop (DLL); a control logic (CONTROL LOGIC); a clock (CLK, /CLK); a clock enable signal (CKE); a chip select signal (/CS); a row address strobe signal (/RAS); a column address strobe signal (/CAS); a write enable signal (/WE); a data write signal (DW); a data strobe signal (DQS); and data (DQ). Note that, methods for controlling the circuits and signals thereof are similar to that of known SDRAM/DDR SDRAM, and the like. Therefore, explanations thereof will be omitted. When memory cells are formed according to the method of manufacturing of the present embodiment, a DRAM having characteristics such as low power consumption, high-speed operation, and high reliability can be realized. Note that, the configuration of a block of the DRAM chip is not limited to the example shown in FIG. 18. Various modifications can be made without deviating from the scope of the present invention, for example, the number of the memory arrays (MEMORY ARRAY) can be increased.

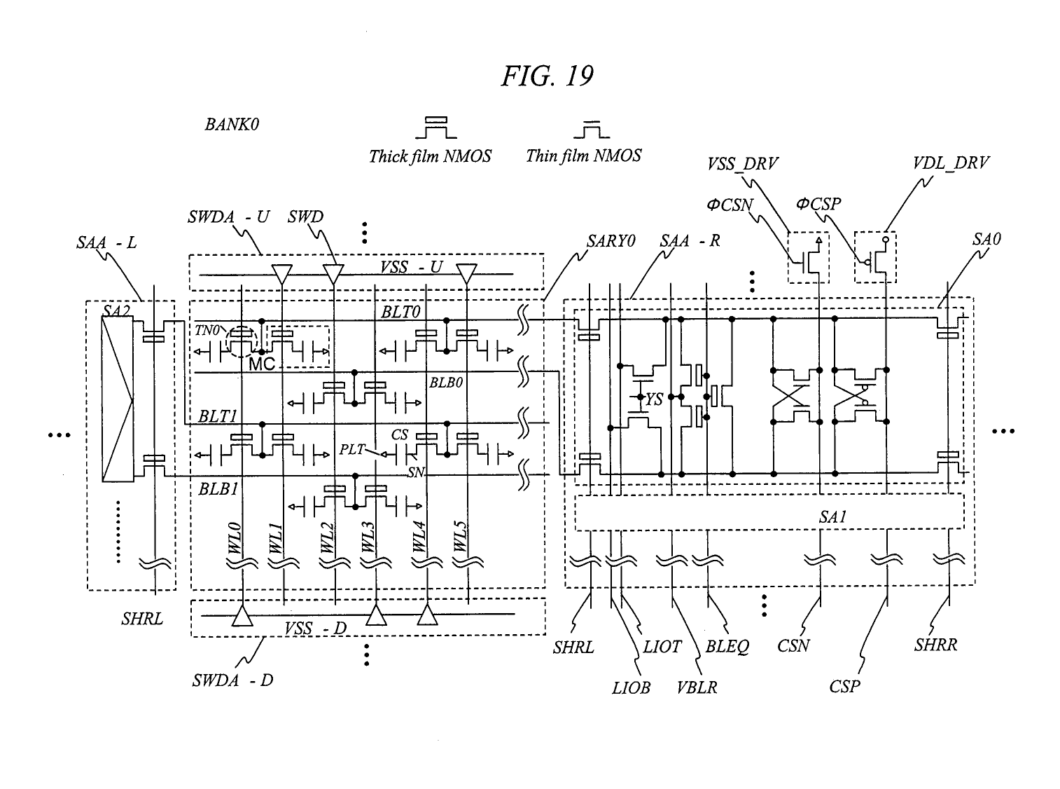

FIG. 19 is a configuration example of a bank BANK0 shown in FIG. 18. The reference characters shown in the diagram are: sense amplifier arrays (SAA-R, SAA-L) using a plurality of sense amplifier circuits (SA0); a sub array (SARY0); and sub word drivers (SWDA-U, SWDA-D). In the example of FIG. 19, a pair of circuits (VSS_DRV, VDL_DRV) for driving common source lines (CSN, CSP) controlled by common source control lines (ΦCSN, ΦCSP) are provided for every sub array (SARY0). The sub word drivers (SWDA-U, SWDA-D) are provided for each sub array and drive sub word lines (WL0, WL1, WL2, WL3, WL4, and WL5) in the sub array (SARY0) by selecting address. Note that, other reference characters represent: shared switches (SHRR, SHRL); a Y switch (YS); local bit lines (LIOT, LIOB); bit lines (BLT0, BLT1, BLB0, BLB1), a pre-charge level (VBLR); a pre-charge control signal (BLEQ); and ground voltages (VSS-U, VSS-D). Pre-charge circuits connected to a memory cell transistor (TN), shared switches (SHR), and the pre-charge control signal (BLEQ) employ a MOS transistor having a thick gate insulating film, namely, thick-film MOS transistor.

The array configuration shown in FIG. 19 is a folded type, and the sense amplifier configuration is in a so-called centered sense system, however, there is no particular limitation on the combination of the array configuration and the sense amplifier system. For example, the array configuration may be a pseudo-folded type or an open type. The configuration of the sense amplifier may be a so-called over drive system or a distributed overdrive system.

Moreover, the memory cell structure of the present embodiment is effective in reduction in power consumption of a DRAM chip when an unselected-level voltage of a word line during a stand-by period is set to a level lower than a ground voltage (VSS). A reason therefor is that the threshold voltage can be increased by setting the voltage level during the stand-by period to a negative voltage. Therefore, a desired threshold voltage can be ensured with a low impurity concentration compared to the case in which a channel impurity is implanted on the assumption that the unselected level of the word line is set to the ground voltage. More specifically, since the electric field of pn junction can be further mitigated, the leakage current can be reduced, and the data retention time can be extended. Note that, detailed descriptions about a method for controlling and an operation waveform of other control signals and circuits with reference to drawings are omitted since they are similar to general methods for controlling DRAM.

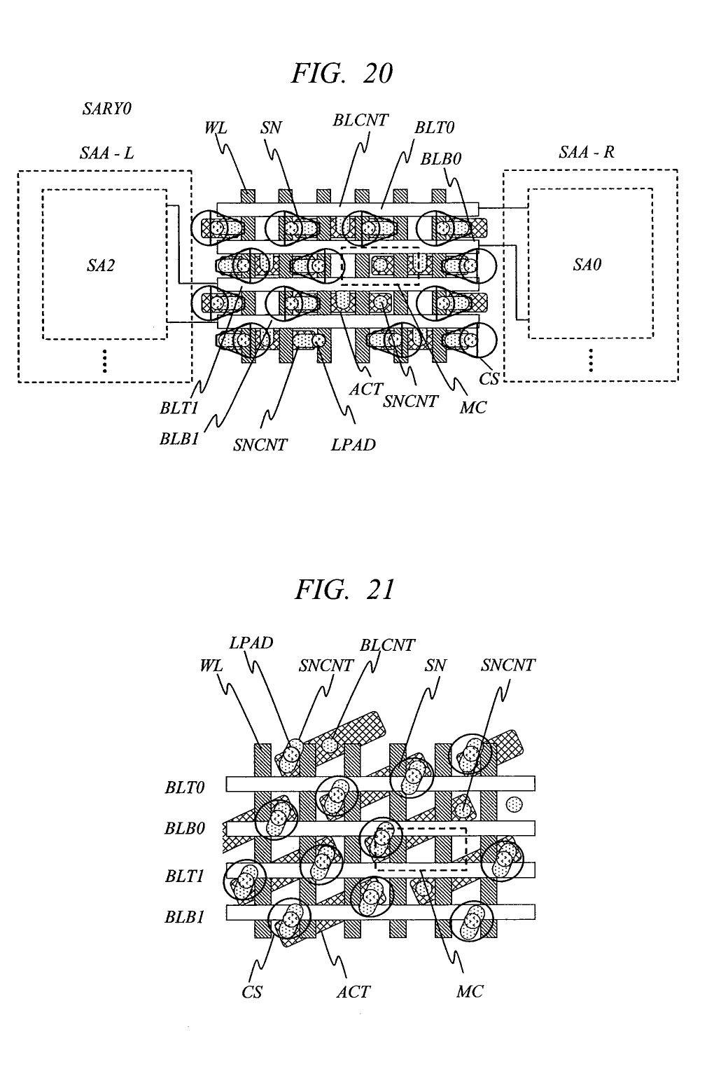

FIG. 20 is a diagram showing a planar layout of the sub array (SARY) shown in FIG. 19 and the sense amplifier arrays (SAA-R, SAA-L) connected to the sub array (SARY). An access transistor (TN0) comprises a sub word line (WL) and a diffusion layer (ACT), and a cell capacitor (CS) comprises a storage node (SN) and a plate electrode (PLT). Other reference characters in the diagram are: a cell contact (SNCNT) for connecting the diffusion layer (ACT) to a wire and a contact thereover; a bit-line contact (BLCNT) connecting bit lines (BLT, BLB) to the diffusion layer (ACT); and a landing pad (LPAD).

The landing pad (LPAD) is a contact connecting the storage node (SN) and the storage-node contact (SNCNT) and is capable of optimizing the position of the cell capacitor (CS). Therefore, the surface area of the cell capacitor (CS) can be increased. As a matter of course, when a sufficient capacity of the cell capacitor (CS) can be ensured, the landing pad (LPAD) is not required to be utilized. In that case, manufacturing cost can be reduced since manufacturing steps can be reduced. The layout of the memory cells of the sub array (SARY) shown in FIG. 20 is a so-called folded-type data line structure. This layout is advantageous in that miniaturization is easy since the diffusion layer (ACT) has a simple rectangular shape.

As the layout of the memory cells (MC), for example, various layouts such as those shown in FIG. 21 to FIG. 23 can be employed other than the layout shown in FIG. 20. FIG. 21 shows a data line structure of pseudo-folded type. A difference from the layout shown in FIG. 20 is that the diffusion layer (ACT) is obliquely disposed with respect to the sub word line (WL). Therefore, since a wide channel width can be effectively reserved, there is an advantage that a large on-current of the access transistor (TN) can be reserved. Thus, when it is combined with the memory cell structure of the present embodiment, a DRAM capable of fast operation can be realized.

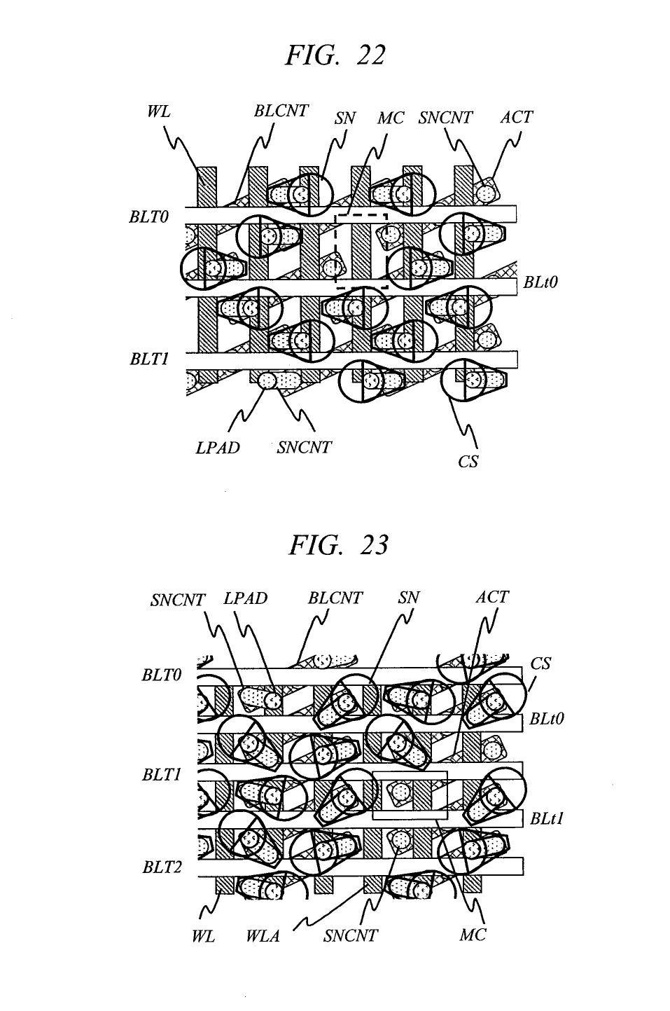

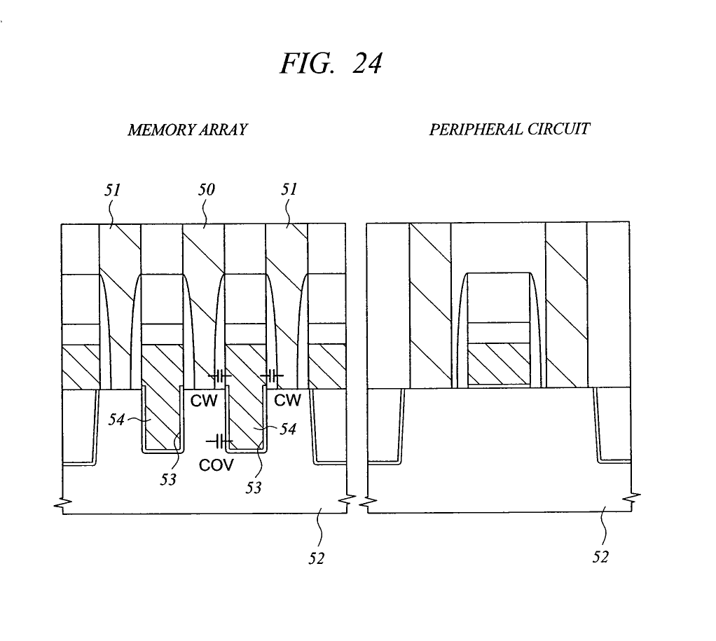

FIG. 22 and FIG. 23 show open-type data line structures. There are advantages that the area of memory cells can be reduced compared to the folded type data line structure. In the layout shown in FIG. 22, a parasitic capacitance of data line can be also reduced since the pitch of data lines is wide. Therefore, in combination with the memory cell structure of the present embodiment, further highly-integrated DRAMs which can be operated at a low voltage can be realized. In the layout shown in FIG. 23, the area of the memory cells can be further reduced more than the layout of FIG. 22. Therefore, further highly-integrated DRAMs can be realized in combination with the memory cell structure of the present embodiment.

The layout of the memory cell that can be applied to the present embodiment is not limited to the layouts shown in FIG. 20 to FIG. 23. For example, in the open-type data line structure of FIG. 23, the diffusion layer (ACT) which is obliquely disposed with respect to the sub word line (WL) may be disposed so as to be orthogonal thereto like FIG. 20. This case has an advantage that miniaturization is easy since the shape is rectangular. Furthermore, there is also an application that, for example, element isolation is performed by sharing the diffusion layers (ACT) of the memory cells which are adjacent in the left and right of a sub word line (WLA) and always applying a low level VSS to the sub word line (WLA). In this case, manufacturing steps can be reduced since isolation regions are not required to be formed in the direction parallel to the data lines.

As described above, according to the present embodiment, the effective channel length of the memory cell can be elongated. More specifically, increase in the leakage current can be suppressed since a channel impurity is not required to be implanted by the concentration more than needed for suppressing the short channel effect. Moreover, the upper surface of the polysilicon film 7n which is a part of the gate electrode 7 is planarized, and the height from the surface of the silicon substrate 1 to the upper surface of the polysilicon film 7n is reduced to about 10 nm. As a result, the surface area of the sidewall parts of word lines over the surface of the silicon substrate is reduced. In other words, the parasitic capacitances of word line formed between the word line and the storage-node contact 17 and between the word line and the bit-line contact 16 are reduced. Thus, a trench type memory cell having a time constant that is equivalent to that of a word line in a planar-type memory cell can be realized. In other words, when the trench type memory cell of the present embodiment is applied, delay in access time (tRCD) can be suppressed. Furthermore, a distance that does not cause insufficient contact is ensured between the W film 8 which is a part of the gate electrode 7 and the source and drain (n-type semiconductor regions 9a, 9b) by the polysilicon film 7n which is the other part of the gate electrode. Therefore, short-circuiting caused by memory cell formation is reduced and a highly-reliable memory cell can be realized.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the embodiment described above, the memory cell transistor is that of trench type and the MOS transistor of the peripheral circuit part is a planar-type transistor similar to conventional ones. However, for example, a trench-type transistor may be used in order to suppress the short channel effect of the MOS transistor constituting a sense amplifier part. Sense amplifiers have to be disposed in conformity with the pitch of bit lines. Consequently, the channel length thereof is elongated and the channel width is narrowed. Therefore, the short channel effect noticeably appears. Thus, when the MOS transistor constituting the sense amplifier part is changed to the trench type, the short channel effect can be effectively suppressed. However, as an adverse effect, operation may be somewhat retarded since the channel length is elongated. In that case, the polysilicon film which is a part of the gate electrode may be formed at the same time in the memory transistor and the peripheral MOS transistor.

The present invention can be applied to a semiconductor device having DRAM.

What is claimed is:

1. A semiconductor device comprising:
a memory cell including a first field effect transistor formed at a main surface of a semiconductor substrate and a capacitative element connected to a source or a drain of the first field effect transistor,
wherein a part of a first gate electrode of the first field effect transistor is embedded in a trench formed in the semiconductor substrate and an upper surface of the first gate electrode located above the surface of the semiconductor substrate.

2. The semiconductor device according to claim 1, further comprising:
a second field effect transistor formed at the main surface of the semiconductor substrate,
wherein a second gate electrode of the second field effect transistor is formed over the main surface of the semiconductor substrate, and
wherein a height from the surface of the semiconductor substrate to the upper surface of the first gate electrode is lower than a height from the surface of the semiconductor substrate to an upper surface of the second gate electrode.

3. The semiconductor device according to claim 1,
wherein the first gate electrode of the first field effect transistor is formed of a first conductive film mainly including silicon and a second conductive film formed on the first conductive film and mainly including a metal having a specific resistance smaller than a specific resistance of the first conductive film; and
wherein an upper surface of the first conductive film is located above the surface of the semiconductor substrate.

4. The semiconductor device according to claim 2,
wherein the first gate electrode of the first field effect transistor is formed of a first conductive film mainly including silicon and a second conductive film formed on the first conductive film and mainly including a metal having a specific resistance smaller than the specific resistance of the first conductive film, and
wherein the second gate electrode of the second field effect transistor is formed of a third conductive film mainly including silicon and a fourth conductive film formed on the third conductive film and mainly including a metal having a specific resistance smaller than a specific resistance of the third conductive film, and
wherein the upper surface of the first conductive film is located above the surface of the semiconductor substrate, and
wherein a height from the surface of the semiconductor substrate to the upper surface of the first conductive film is lower than a height from the surface of the semiconductor substrate to an upper surface of the third conductive film.

5. The semiconductor device according to claim 2, further comprising
a first cap insulating film formed over the first gate electrode of the first field effect transistor and a second cap insulating film formed over the second gate electrode of the second field effect transistor;
wherein a height from the surface of the semiconductor device to an upper surface of the first cap insulating film and a height from the surface of the semiconductor substrate to an upper surface of the second cap insulating film are the same.

6. The semiconductor device according to claim 1, further comprising
a second field effect transistor of a first conductive type formed on the main surface of the semiconductor substrate and a third field effect transistor of a second conductive type formed on the main surface of the semiconductor substrate;
wherein a second gate electrode of the second field effect transistor and a third gate electrode of the third field effect transistor are formed over the main surface of the semiconductor substrate, and
wherein the height from the surface of the semiconductor substrate to the upper surface of the first gate electrode of the first field effect transistor is lower than a height from the surface of the semiconductor substrate to an upper surface of the second gate electrode of the second field effect transistor and a height from the surface of the semiconductor substrate to an upper surface of the third gate electrode of the third field effect transistor.

7. The semiconductor device according to claim 6,
wherein the second gate electrode of the second field effect transistor is formed of a third conductive film mainly comprising silicon of the first conductive type, and a second conductive film formed over the third conductive film and mainly comprising a metal having a specific resistance smaller than that of the third conductive film, and
wherein the third gate electrode of the third field effect transistor is formed of a fourth conductive film mainly including silicon of a second conductive type and a second conductive film formed over the fourth conductive film and mainly including a metal having a specific resistance smaller than a specific resistance of the fourth conductive film.

8. A method of manufacturing a semiconductor device having a memory cell which includes a first field effect transistor formed in a main surface of a semiconductor substrate and a capacitative element connected to a source or a drain of the first field effect transistor, comprising:
(a) forming a first insulating film over the main surface of the semiconductor substrate;
(b) etching the first insulating film and the semiconductor substrate so as to form a trench;
(c) forming a first gate insulating film of the first field effect transistor over the surface of the semiconductor device exposed in the trench;
(d) forming a first conductive film for the first gate electrode over the first insulating film including the trench after the step (c); and
(e) polishing the first conductive film by chemical mechanical planarization and causing the surface of the first insulating film to be exposed so that the first conductive film is formed having a part thereof is embedded in the trench whose upper surface is projected above the surface of the semiconductor substrate.

9. The method of manufacturing the semiconductor device according to claim 8,
wherein, after the step (e), a second conductive film mainly including a metal which has a specific resistance smaller than a specific resistance of the first conductive film is formed over the first conductive film, and the second conductive film is subsequently patterned so as to form the first gate electrode formed of a stacked film of the first conductive film and the second conductive film.

10. The method of manufacturing the semiconductor device according to claim 8,
wherein the first conductive film is a conductive film mainly including silicon, and the second conductive film is a conductive film mainly including tungsten.

11. A method of manufacturing a semiconductor device having a memory cell which includes a first field effect transistor formed on a main surface of a semiconductor substrate and a capacitative element connected to a source or a drain of the first field effect transistor, and a second field effect transistor formed on a main surface of the semiconductor substrate, comprising:
(a) forming a first insulating film over the main surface of the semiconductor substrate;
(b) etching the first insulating film and the semiconductor substrate so as to form a trench;
(c) forming a first gate insulating film of the first field effect transistor over the surface of the semiconductor device exposed in the trench;
(d) forming a first conductive film for the first gate electrode over the first insulating film including the trench after the step (c); and
(e) polishing the first conductive film by chemical mechanical planarization and causing the surface of the first insulating film to be exposed so that the first conductive film is formed having a part thereof is embedded in the trench whose upper surface is projected above the surface of the semiconductor substrate, and
after the step (e), a process of forming a second gate electrode of the second field effect transistor includes the steps of:
(f) forming a second gate insulating film of the second field effect transistor over the surface of the semiconductor substrate;
(g) forming a third conductive film for the second gate electrode over the second gate insulating film; and
(h) patterning the third conductive film.

12. The method of manufacturing the semiconductor device according to claim 11,
wherein the first and third conductive films are formed of conductive films mainly comprising silicon, a second conductive film mainly comprising a metal having a specific resistance smaller than that of the first and third conductive films is formed over the first and third conductive films after the step (g) and before the step (h), and the second conductive film and the third conductive film are patterned in the step (h) so that the first gate electrode formed of a stacked film of the first conductive film and the second conductive film and the second gate electrode formed of a stacked film of the third conductive film and the second conductive film are formed.

13. The method of manufacturing the semiconductor device according to claim 11,
wherein a height from the surface of the semiconductor substrate to an upper surface of the first gate electrode is smaller than a height from the surface of the semiconductor substrate to an upper surface of the second gate electrode.

14. The method of manufacturing the semiconductor device according to claim 11,
wherein a height from the surface of the semiconductor substrate to the upper surface of the first conductive film is smaller than a height from the surface of the semiconductor substrate to an upper surface of the third conductive film.
